(19) United States
(12) Patent Application Publication
(10) Pub. No.: US 2014/0110244 A1
(43) Pub. Date: Apr. 24, 2014

(54) SUPERSONIC BEAM APPARATUS AND CLUSTER ION BEAM FORMING METHOD

(71) Applicant: CANON KABUSHIKI KAISHA, Tokyo (JP)

(72) Inventor: Kota Iwasaki, Atsugi-shi (JP)

(73) Assignee: CANON KABUSHIKI KAISHA, Tokyo (JP)

(21) Appl. No.: 14/049,483

(22) Filed: Oct. 9, 2013

(30) Foreign Application Priority Data
Oct. 23, 2012 (JP) 2012-233888

(51) Int. Cl. C23C 14/34

(52) U.S. Cl. CPC C23C 14/3442
USPC 204/192.11; 204/298.04; 204/298.03; 204/298.36; 204/298.32; 204/192.34

(57) ABSTRACT

Provided is a supersonic beam apparatus including a nozzle for injecting a gas at a supersonic velocity into a vacuum; a skimmer arranged at a downstream of the nozzle; and an ionization part for ionizing a particle in a supersonic beam formed by the skimmer from the gas injected from the nozzle to form a cluster ion beam, wherein a set position of the skimmer is one of a maximum position where an amount of cluster generation in a relationship of the amount of cluster generation with respect to a distance between the nozzle and the skimmer is maximized and a position closer to the nozzle than the maximum position.

### BACKGROUND OF THE INVENTION

1. Field of the Invention

The present invention relates to an apparatus for generating a supersonic molecule or a cluster ion beam by injecting a gas into a vacuum.

2. Description of the Related Art

A cluster ion beam is an ion beam that is obtained by forming a supersonic beam by injecting a high pressure gas from a nozzle into a vacuum and performing electron impact or photoionization of a particle clustered by cooling due to an adiabatic expansion caused by the injecting.

Irradiation of a solid surface with the cluster ion is used in a surface processing such as etching, sputtering, and deposition. Further, irradiation of a polymer with the cluster ion enables the polymer to be ionized while suppressing a fragmentation, and hence it is also effective to apply the cluster ion to a surface analysis apparatus.

A supersonic beam apparatus for generating the cluster ion includes a cluster generation part, an ionization part, a beam control part, and an irradiation part. The respective parts construct a vacuum chamber that is evacuated by a vacuum pump.

A nozzle is arranged in the cluster generation part, and a gas injected into the cluster generation part through the nozzle is freely expanded under a reduced pressure atmosphere to form a supersonic beam.

In the supersonic beam, the gas is cooled, and then a cluster is generated. In the cluster generation part, a skimmer arranged at a downstream of the nozzle forms a cluster beam from the supersonic beam containing the clusters. A part of the cluster beam is guided to the ionization part and then ionized, thus generating a cluster ion beam.

The cluster ion beam is controlled by the beam control part to be accelerated, decelerated, converged, or diverged, and then an object to be processed or a specimen arranged in an irradiation chamber is irradiated with the cluster ion beam (see U.S. Pat. No. 6,486,478).

For this type of apparatus that irradiates the object to be treated or the specimen with the cluster ion beam, increase of etching rate or increase of deposition rate is required. Also in surface analysis, increase of sensitivity or decrease of measurement time is required. In order to meet any one of these requirements, an electric current of the cluster ion beam needs to be increased. Further, it may be effective to increase the size of the cluster.

It has been known that increase of a pressure of the gas introduced to the nozzle is effective in order to increase an amount of cluster generation in the supersonic beam or to increase the size of the cluster (see Journal of Chemical Physics, 56, 1793 (1972)).

For the above-mentioned reason, if the pressure of the gas introduced to the nozzle (i.e., gas introduction pressure) is increased, the amount of gas introduced into the vacuum chamber is increased, and hence the pressure inside the vacuum chamber is increased.

On the other hand, density of the cluster in the supersonic beam is not uniform, but is determined by type of gas, the gas introduction pressure, the pressure inside the vacuum chamber, and the like. Therefore, even when the gas introduction pressure is increased in order to obtain a required cluster, in some cases, the skimmer may not be set at a position in the supersonic beam where the cluster density is high, so that it is difficult for the skimmer to sufficiently extract the cluster from the supersonic beam.

Further, the increase of the pressure inside the vacuum chamber shortens the mean free path of a residual gas, thereby increasing a frequency of collision between the residual gas and the cluster ion.

The collision with the residual gas causes a decomposition of the cluster ion. Therefore, there has been a problem that the cluster ion beam generated by the supersonic beam is attenuated due to the residual gas before irradiating the object to be treated or the specimen with the cluster ion beam.

As described above, in the conventional supersonic beam apparatus, there has been a problem that, when the gas introduction pressure is increased in order to increase the intensity of the cluster ion beam, the pressure inside the vacuum chamber is increased to decrease utilization efficiency of the cluster ion beam.

### SUMMARY OF THE INVENTION

The present invention has been achieved in view of the above-mentioned problems, and it is an object of the present invention to provide a supersonic beam apparatus configured to efficiently extract the clusters generated in the supersonic beam.

A supersonic beam apparatus according to one embodiment of the present invention includes: a nozzle for injecting a gas at a supersonic velocity into a vacuum; a skimmer arranged at a downstream of the nozzle; and an ionization part for ionizing a particle in a supersonic beam formed by the skimmer from the gas injected from the nozzle to form a cluster ion beam, in which a set position of the skimmer is one of a maximum position where an amount of cluster generation in a relationship of the amount of cluster generation with respect to a distance between the nozzle and the skimmer is maximized and a position closer to the nozzle than the maximum position.

According to the present invention, it is possible to provide the supersonic beam apparatus configured to efficiently extract the clusters generated in the supersonic beam.

Further features of the present invention will become apparent from the following description of exemplary embodiments with reference to the attached drawings.

### BRIEF DESCRIPTION OF THE DRAWINGS

FIG. 1A is a schematic diagram of a supersonic beam apparatus according to the present invention, FIG. 1B is a schematic diagram of a supersonic beam injected from a nozzle, FIG. 1C is a schematic diagram illustrating positions of a skimmer and a nozzle, and FIG. 1D is a graph showing a yield of a cluster.

FIG. 2A is a schematic diagram of a cluster generation part according to an embodiment of the present invention, FIG. 2B is a schematic diagram of a cluster generation part according to a second embodiment of the present invention, FIG. 2C is a schematic diagram of a cluster generation part according to a third embodiment of the present invention, and FIG. 2D is a schematic diagram of a cluster generation part in which the skimmer is movable.

FIG. 3A is a schematic diagram of a cluster generation part according to a fifth embodiment of the present invention, and FIG. 3B is a schematic diagram of a cluster generation part according to a sixth embodiment of the present invention.

FIG. 4A is a graph showing a relationship between the mean free path and the pressure according to the second embodiment, and FIG. 4B is a graph showing a relationship between a distance between a Mach disk and the nozzle and the pressure according to the third embodiment.

### DESCRIPTION OF THE EMBODIMENTS

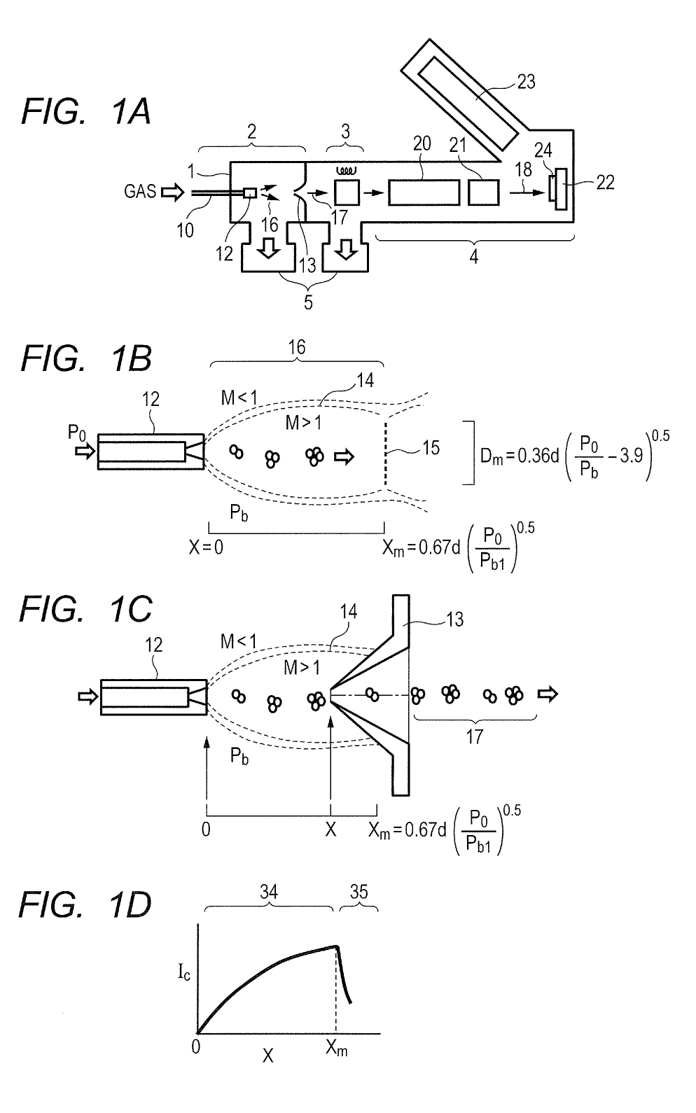

An irradiation method with a cluster ion beam by a supersonic beam apparatus according to one embodiment of the present invention is described with reference to FIG. 1A.

The supersonic beam apparatus includes a cluster generation part 2, an ionization part 3, and an irradiation part 4. The respective parts construct a vacuum chamber 1, and the supersonic beam apparatus further includes a vacuum evacuation system including a vacuum pump 5 and a signal processing system (not shown).

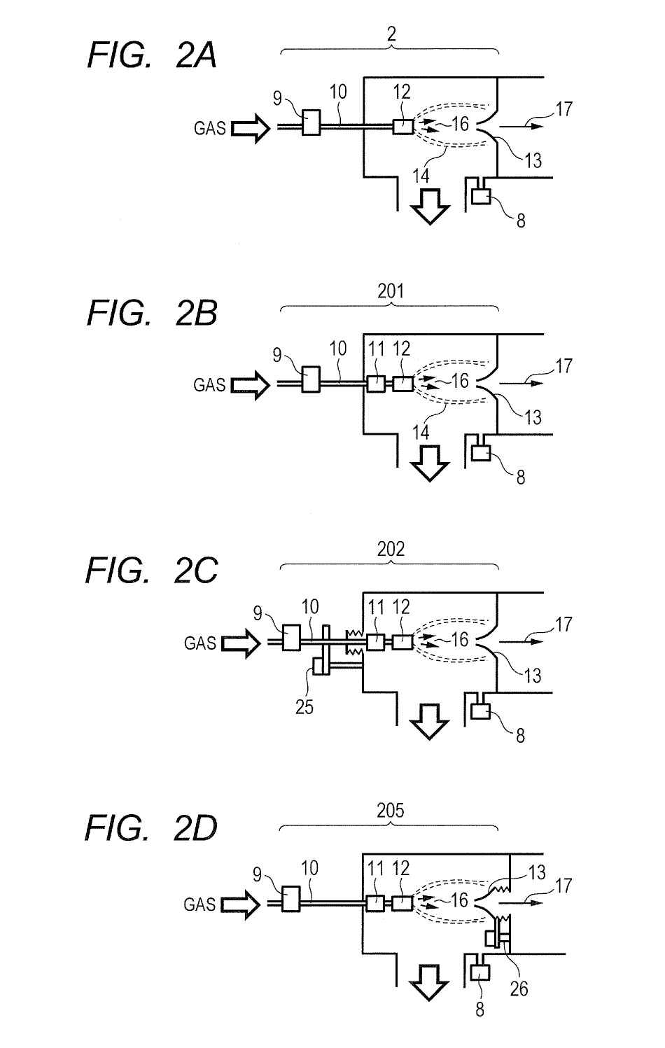

The cluster generation part 2 includes a gas pressure gauge 9, a vacuum gauge 8, a gas introduction pipe 10, a nozzle 12 arranged in the vacuum chamber 1, and a skimmer 13 (see FIG. 2A).

The gas introduction pipe 10 supplies a noble gas such as Ar, Ne, He, or Kr, a molecular gas such as CO₂, CO, N₂, O₂, NO₂, SF₆, Cl₂, or NH₃, an alcohol such as ethanol, methanol, or isopropyl alcohol, water, and the like to the nozzle 12. Further, the water or the alcohol may be mixed with an acid or a base.

The gas introduction pressure is measured by the gas pressure gauge 9 connected to the gas introduction pipe 10. It is preferred that the gas introduction pressure be 0.1 atm to 20 atm. However, the gas introduction pressure may be 0.001 atm to 0.1 atm and may be 20 atm to 100 atm.

As illustrated in FIG. 1B, when a gas is injected from the nozzle 12 into a vacuum inside the vacuum chamber of the cluster generation part 2, the supersonic gas generates a barrel shock wave 14, which is a kind of shock wave, and a Mach disk 15. A distance Xₘ between the Mach disk 15 and the nozzle 12 is expressed by Equation 1. A diameter Dₘ of the Mach disk 15 is expressed by Equation 2.

$$\begin{matrix}{X}_{m} = 0.67 {d ( \frac{{P}_{0}}{{P}_{b}} )}^{0.5} & ( Equation 1 ) \\ {D}_{m} = 0.36 {d ( \frac{{P}_{0}}{{P}_{b}} - 3.9 )}^{0.5} & ( Equation 2 )\end{matrix}$$

where d is diameter of the nozzle 12, P₀ is gas introduction pressure to the nozzle 12, and P_{b} is pressure inside the vacuum chamber of the cluster generation part 2. P_{b} is measured by the vacuum gauge 8 connected to the vacuum chamber of the cluster generation part 2.

Focusing on a radial direction with respect to a traveling direction of a supersonic beam 16, the gas velocity is of the supersonic velocity or slower outside the barrel shock wave 14, but the gas velocity exceeds the supersonic velocity within the barrel shock wave 14. On the other hand, focusing on the traveling direction of the supersonic beam, the gas velocity exceeds the supersonic velocity between the nozzle 12 and the Mach disk 15, but the gas velocity is of the supersonic velocity or slower on the other side of the nozzle 12 after passing through the Mach disk 15 (i.e., a downstream direction).

In a supersonic area surrounded by the nozzle 12, the barrel shock wave 14, and the Mach disk 15, the gas is cooled by the adiabatic expansion, and hence a supersonic beam containing a cluster is generated as expressed by Equation 3.

dI_{c}=I_{c}·ηᵣ^{k}·σ·dX (Equation 3)

where I_{c} is flux of the cluster, X is distance between the nozzle 12 and the skimmer 13, ηᵣ is gas density in the supersonic area, k is coefficient that depends on the type of the gas, and σ is physical amount corresponding to a collision cross-section of the cluster and the gas, which has the dimension of area when k equals 1.

A relationship between the distance from the nozzle 12 and the cluster flux is shown in FIG. 1D. In a first area 34, the cluster flux is increased as the distance is increased from the nozzle 12 based on the relationship of Equation 3.

On the other hand, in a second area 35, when the cluster arrives at the Mach disk 15, the cluster is heated and decomposed by the shock wave, and hence the cluster flux is decreased (Equation 4). Therefore, the cluster flux is maximized at an upstream side of the Mach disk 15.

$$\frac{d {I}_{c}}{d t} ∝ - Γ = \frac{p}{\sqrt{2 π {mk}^{′} T}} \qquad ( Equation 4 )$$

where Γ is amount of gas evaporation from a surface of the cluster, p is vapor pressure, m is mass of the gas molecule, k′ is Boltzmann constant, and T is temperature.

For the first and second areas, calculation may be performed with Equations 3 and 4, respectively. The relationship of FIG. 1D may be experimentally obtained by, for example, a method of measuring an amount of cluster ion generation when the distance between the nozzle 12 and the skimmer 13 is changed.

The skimmer 13 arranged at the downstream of the nozzle 12 generates a cluster beam 17 from a particle in the supersonic beam 16, as illustrated in FIG. 1C.

A positional relationship between the nozzle 12 and the skimmer 13 is set so as to satisfy a relationship of Equation 5.

0≦X≦Xₘ (Equation 5)

When Equation 5 is not satisfied, the skimmer 13 is located at the downstream of the Mach disk 15 with respect to the nozzle 12. In this case, the generated cluster beam 17 passes through the Mach disk 15 that is a shock wave front, and hence the cluster is heated and decomposed by the shock wave, and a current value of the available cluster ion is decreased.

Therefore, by satisfying the condition of Equation 5, the skimmer 13 can form the cluster beam before the cluster passes through the Mach disk 15 as illustrated in FIG. 1C, and hence the heat decomposition of the cluster due to the shock wave is suppressed, and the cluster can be efficiently used.

A set position of the skimmer 13 is a maximum position where the amount of the cluster generation in the relationship of the amount of cluster generation with respect to the distance between the nozzle 12 and the skimmer 13 is maximized or a position closer to the nozzle 12 than the maximum position.

From the relationship of FIG. 1D, the position of the skimmer 13 may be located at the more upstream side than Xₘ by the mean free path of the gas and further by about 10 times the mean free path. It is because with the distance as large as the mean free path or 10 times larger than the mean free path, an influence of the decomposition of the cluster is relatively small.

The position of the skimmer 13 may be between X₀ and Xₘ, where X₀ is a position where when the first area is a curved line, the second-order differential value of the curved line with respect to X equals zero. In this case, a change of the yield of the cluster with respect to the position of the skimmer 13 becomes more modest.

In addition, by a distance D between an opening of the skimmer 13 and a center axis of the nozzle 12 satisfying Equation 6, the heating decomposition of the generated cluster when passing through the Mach disk 15 can be suppressed.

0<D<Dₘ (Equation 6)

The cluster beam 17 enters into the ionization part 3. In the ionization part 3, an electron source such as a thermal filament is arranged. Electrons generated by the electron source are collided with the cluster beam 17 to ionize some of atoms or molecules constituting the cluster by electron impact, thus generating a cluster ion beam 18.

Note that, the ionization may be performed by using an electromagnetic wave such as a laser, an excited atom or molecule, or an ionizing radiation, as well as the electron impact.

Thereafter, the cluster ion beam 18 enters into the irradiation part 4. The irradiation part 4 includes a mass selector 20, a focusing lens 21, an irradiation stage 22, and an analysis device 23.

A cluster ion having a proper size is selected by the mass selector 20 and accelerated/decelerated and focused by the focusing lens 21. Then, an object 24 to be irradiated, which is held by the irradiation stage 22, is irradiated with the cluster ion.

The object 24 to be irradiated is sputtered or etched by the cluster ion. A secondary ion or a neutral particle generated from the object 24 to be irradiated is analyzed by the analysis device 23 as necessary.

When a mass analyzer is used as the analysis device 23, a mass analysis of the secondary ion generated by the cluster ion can be performed. When a neutral particle detector including an ionization device is used as the analysis device 23, a mass analysis of the neutral particle generated by the cluster ion can be performed.

### Second Embodiment

A cluster generation part 201 of a supersonic beam apparatus according to a second embodiment of the present invention is illustrated in FIG. 2B.

The supersonic beam apparatus according to the second embodiment is similar to the supersonic beam apparatus according to the first embodiment except that the cluster generation part 201 includes a gas flow rate control part 11.

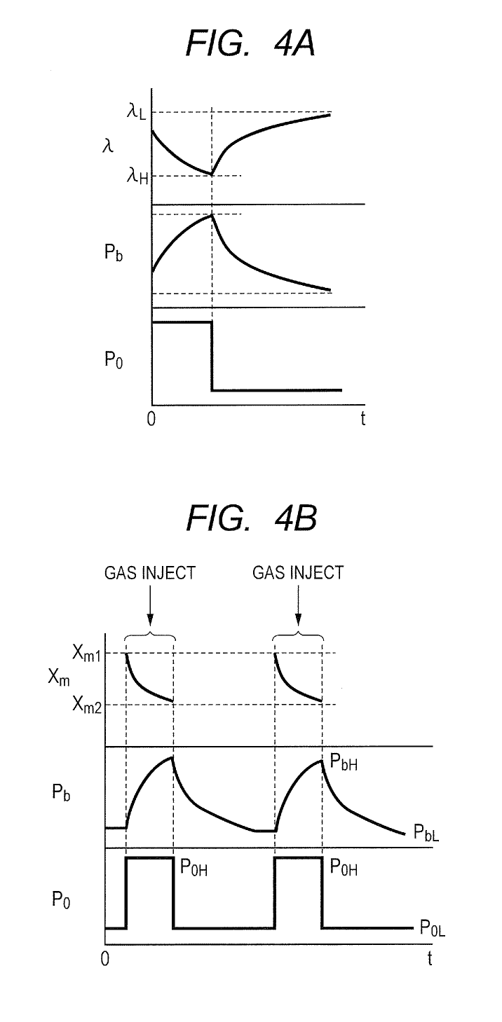

In the second embodiment, the gas flow rate control part 11 changes the flow rate of the gas supplied from the nozzle 12, as shown in FIG. 4A. The gas flow rate control part 11 may be arranged outside the vacuum chamber. Further, the gas flow rate control part 11 may be arranged inside the vacuum chamber of the cluster generation part 201 so that a length of a pipe between the nozzle 12 and the gas flow rate control part 11 can be shortened, thereby increasing a response speed of the gas flow rate control.

In a first state where the flow rate of the gas is large, the gas pressure applied to the nozzle 12 is high (P_{0H}) and a cooling effect due to the adiabatic expansion is large, and hence the cluster density is increased.

On the other hand, when the first state is continued, not only the pressure inside the vacuum chamber of the cluster generation part 201 is increased, but also pressures of the ionization part 3 and the irradiation part 4 are increased due to the gas inflow through the opening of the skimmer 13.

As a consequence, the mean free path of a residual gas is shortened, and hence the frequency of the collision between the cluster beam and the residual gas is increased, which causes a problem of attenuating the cluster beam. At this time, the cluster ion beam is also attenuated.

To cope with this problem, in the second embodiment, the gas flow rate control part 11 changes the gas pressure applied to the nozzle to a second state where the gas pressure is low (P_{OL}), to reduce the flow rate of the gas supplied from the nozzle. The purpose of this operation is to prevent the pressure of the cluster generation part 201 from being excessively increased.

The mean free path of the residual gas inside the vacuum chamber of the cluster generation part 201 can be maintained to be a predetermined value (λH) or larger. The predetermined value may be a geometric size of the vacuum chamber of the cluster generation part 201, for example, the distance X between the nozzle 12 and the skimmer 13. Further, the predetermined value may be an inner diameter or a length of the vacuum chamber of the cluster generation part 201. Note that, the flow rate of the gas may be controlled so that the mean free path of the residual gas inside the ionization part 3 or the irradiation part 4 becomes a predetermined value or larger.

Note that, a value of a nitrogen gas that can be calculated by Equation 7 may be used for the mean free path. Here, a unit of λ is [mm], and a unit of P_{b} is [Pa].

λ=6.6/P_{b} (Equation 7)

With this control, the density of the cluster can be increased, and the attenuation of the cluster beam due to the residual gas can be suppressed.

### Third Embodiment

A vacuum chamber of a cluster generation part 202 according to a third embodiment of the present invention is illustrated in FIG. 2C.

A supersonic beam apparatus according to the third embodiment is similar to the supersonic beam apparatus according to the second embodiment except that the cluster generation part 202 includes a nozzle driving mechanism 25 that adjusts a position of the nozzle 12 as a distance adjusting mechanism for adjusting the distance between the nozzle 12 and the skimmer 13.

In the third embodiment, in the same manner as in the second embodiment, the gas flow rate control part 11 changes the flow rate of the gas supplied from the nozzle 12.

As shown in FIG. 4B, the pressure inside the vacuum chamber of the cluster generation part 202 is increased when the gas is injected from the nozzle. From the relationship of Equation 1, the Mach disk 15 comes closer to the nozzle 12.

When the skimmer 13 is located at the downstream of the Mach disk 15 with respect to the nozzle 12, the cluster is attenuated due to the heating operation of the shock wave as described above.

To cope with this problem, in the third embodiment, a change range of the position of the Mach disk 15 is obtained in advance from change ranges of the gas introduction pressure and the pressure inside the vacuum chamber of the cluster generation part 202 by using Equation 1. The skimmer 13 is then set at a position where the distance between the nozzle 12 and the skimmer 13 is shorter than the minimum distance between the Mach disk 15 and the nozzle 12.

The position of the Mach disk 15 may be obtained in advance by experimentally determining the relationship of FIG. 1D using a method such as measuring the amount of cluster ion generation when the distance between the nozzle 12 and the skimmer 13 is changed. In this case, a position where the amount of cluster ion generation is maximized may be used as the position of the Mach disk 15.

Further, as illustrated in FIG. 2D, the position of the skimmer 13 may be adjusted with respect to the nozzle 12 by using a skimmer driving mechanism 26.

When the flow rate of the gas injected from the nozzle 12 is increased, the distance adjusting mechanism for adjusting the distance of the skimmer 13 with respect to the nozzle 12, such as the nozzle driving mechanism 25 and the skimmer driving mechanism 26, increases the distance between the nozzle 12 and the skimmer 13 as compared with the distance before the increase of the flow rate of the gas injected from the nozzle 12. When the flow rate of the gas injected from the nozzle 12 is decreased, the distance adjusting mechanism reduces the distance between the nozzle 12 and the skimmer 13 as compared with the distance before the decrease of the flow rate of the gas injected from the nozzle 12.

The gas introduction pressure may be measured by using the gas pressure gauge 9 connected to the gas introduction pipe 10.

The pressure inside the vacuum chamber of the cluster generation part 202 may be measured by using a vacuum gauge 8 connected to the vacuum chamber. Further, a calculated value obtained by dividing a gas introduction amount obtained from the gas introduction pressure and a conductance of the nozzle 12 by an evacuation speed of the vacuum pump may be used for the pressure inside the vacuum chamber of the cluster generation part 202.

With this arrangement, even when the flow rate of the gas supplied from the nozzle 12 is changed, the skimmer can form the cluster beam before the cluster passes through the Mach disk 15, and hence the heating decomposition of the cluster due to the shock wave can be suppressed and the cluster can be efficiently used.

### Fourth Embodiment

A fourth embodiment of the present invention is similar to the third embodiment except for a set position of the skimmer 13.

In the fourth embodiment, in the case where when the gas is injected from the nozzle 12, the pressure inside the vacuum chamber of the cluster generation part 202 is not substantially changed or the change is ignorable, the skimmer 13 may be arranged at a position where the distance between the nozzle 12 and the skimmer 13 is shorter than the distance between the Mach disk 15 and the nozzle 12 when the gas introduction pressure is minimized. The same holds true for a case where the gas introduction amount is minimized.

In the fourth embodiment, the heating decomposition due to the shock wave can be suppressed and the cluster can be efficiently used. Further, in the fourth embodiment, the positioning of the skimmer 13 can be easily performed.

### Fifth Embodiment

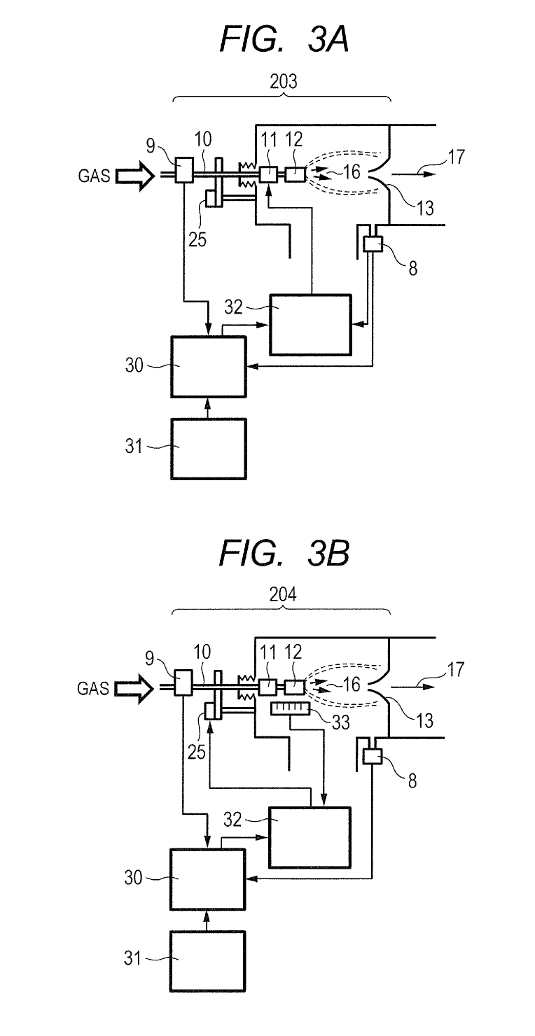

A cluster generation part 203 of a supersonic beam apparatus according to a fifth embodiment of the present invention is illustrated in FIG. 3A.

The supersonic beam apparatus according to the fifth embodiment is similar to the supersonic beam apparatus according to the second embodiment except that the supersonic beam apparatus according to the fifth embodiment further includes a processing part 30 connected to the gas pressure gauge 9 and the vacuum gauge 8, a data storage part 31, a determination control part 32, and a gas flow rate control part 11 connected to the determination control part 32.

When the gas is injected from the nozzle 12 into the vacuum chamber of the cluster generation part 203, data of the gas introduction pressure is sent from the gas pressure gauge 9 to the processing part 30. Further, data of the pressure inside the vacuum chamber of the cluster generation part 203 is sent from the vacuum gauge 8 to the processing part 30.

The processing part 30 obtains, from the data of the gas introduction pressure, diameter data of an opening of the nozzle 12 stored in advance in the data storage part 31, and distance data between the nozzle 12 and the skimmer 13, a set pressure inside the vacuum chamber of the cluster generation part 203, with which the position of the Mach disk 15 satisfies the relationship of Equation 3. The set pressure is a single value or a value having a range as described in the first embodiment.

Note that, the position of the Mach disk 15 may be sequentially calculated by using Equation 1. A relationship among the position of the Mach disk 15, the gas pressure data, and the vacuum data may be stored in advance in the data storage part 31.

The relationship of FIG. 1D may be experimentally obtained by a method of measuring the amount of cluster ion generation when changing the distance between the nozzle 12 and the skimmer 13, and stored in the data storage part 31 together with the gas pressure data and the vacuum data.

The data of the set pressure inside the cluster generation part 203 is sent to the determination control part 32. The determination control part 32 receives actual pressure data inside the vacuum chamber of the cluster generation part 203 from the vacuum gauge 8, and compares the set pressure data with the actual pressure data.

For example, when the actual pressure inside the vacuum chamber of the cluster generation part 203 exceeds the set pressure, the determination control part 32 sends to the gas flow rate control part a command to reduce the flow rate of the gas.

Note that, the control of the flow rate of the gas may include increasing or decreasing the conductance in a continuous manner or in a pulsed manner. The control of the flow rate of the gas may further include changing the gas introduction pressure.

With this function, the cluster can be efficiently used by satisfying the relationship of Equation 3 without adjusting the distance between the nozzle 12 and the skimmer 13.

### Sixth Embodiment

A cluster generation part 204 of a supersonic beam apparatus according to a sixth embodiment of the present invention is illustrated in FIG. 3B.

The supersonic beam apparatus according to the sixth embodiment is similar to the supersonic beam apparatus according to the second embodiment except that the supersonic beam apparatus according to the sixth embodiment further includes a position detection part 33 for the nozzle 12, a processing part 30 connected to the gas pressure gauge 9 and the vacuum gauge 8, a data storage part 31, a nozzle driving mechanism 25 connected to the processing part 30 and the position detection part 33 for the nozzle 12.

When the gas is injected from the nozzle 12 into the vacuum chamber of the cluster generation part 204, the gas pressure data is sent from the gas pressure gauge 9 to the processing part 30. Further, the vacuum data inside the vacuum chamber of the cluster generation part 204 is sent from the vacuum gauge 8 to the processing part 30.

The processing part 30 obtains the position of the Mach disk 15 from the above-mentioned two types of data and the diameter data of the opening of the nozzle 12 stored in advance in the data storage part 31.

The position Xₘ of the Mach disk 15 may be sequentially calculated by using Equation 1. A relationship among the position Xₘ of the Mach disk 15, the gas pressure data, and the vacuum data may be stored in advance in the data storage part 31.

The relationship of FIG. 1D may be experimentally obtained by, for example, a method of measuring the amount of cluster ion generation when the distance between the nozzle 12 and the skimmer 13 is changed. In this case, a maximum position where the amount of cluster ion generation is maximized can be used as the position of the Mach disk 15.

The position data of the Mach disk is sent from the processing part 30 to the nozzle driving mechanism 25. The nozzle driving mechanism 25 adjusts the position of the nozzle 12 so that the skimmer 13 may come closer to the nozzle 12 than the Mach disk 15, based on the position data of the Mach disk and nozzle position data received from the position detection part 33 for the nozzle 12.

Note that, in the same manner as in the first embodiment, the position of the skimmer 13 may be located at the more upstream side than Xₘ by the mean free path of the gas and further by about 10 times the mean free path. Further, the position of the skimmer 13 may be between X₀ and Xₘ.

The position of the skimmer 13 may be adjusted by the skimmer driving mechanism 26 illustrated in FIG. 2D, instead of adjusting the position of the nozzle 12.

With this function, the cluster can be efficiently used even when the gas introduction pressure or the pressure inside the vacuum chamber of the cluster generation part 204 is changed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-233888, filed Oct. 23, 2012, which is hereby incorporated by reference herein in its entirety.

What is claimed is:

1. A supersonic beam apparatus, comprising:
a nozzle for injecting a gas at a supersonic velocity into a vacuum;
a skimmer arranged at a downstream of the nozzle; and
an ionization part for ionizing a particle in a supersonic beam formed by the skimmer from the gas injected from the nozzle to form a cluster ion beam,
wherein a set position of the skimmer is one of a maximum position where an amount of cluster generation in a relationship of the amount of cluster generation with respect to a distance between the nozzle and the skimmer is maximized and a position closer to the nozzle than the maximum position.

2. A supersonic beam apparatus according to claim 1, wherein the set position of the skimmer is between the maximum position where the amount of cluster generation in the relationship of the amount of cluster generation with respect to the distance between the nozzle and the skimmer is maximized and a position that is closer to the nozzle than the maximum position by a mean free path of the gas.

3. A supersonic beam apparatus according to claim 1, wherein the set position of the skimmer is between the maximum position where the amount of cluster generation in the relationship of the amount of cluster generation with respect to the distance between the nozzle and the skimmer is maximized and a position where a second-order differential value of the amount of cluster generation in the relationship of the amount of cluster generation with respect to the distance between the nozzle and the skimmer equals zero.

4. A supersonic beam apparatus according to claim 1, wherein the maximum position where the amount of cluster generation is maximized is a position of a Mach disk formed by the gas injected from the nozzle in the absence of the skimmer

5. A supersonic beam apparatus according to claim 1, wherein a diameter of an opening of the skimmer is smaller than a diameter of the Mach disk.

6. A supersonic beam apparatus according to claim 1, further comprising a gas flow rate control part for controlling a flow rate of the gas injected from the nozzle.

7. A supersonic beam apparatus according to claim 1, further comprising a distance adjusting mechanism for adjusting the distance between the nozzle and the skimmer by adjusting a set position of at least one of the nozzle and the skimmer.

8. A supersonic beam apparatus according to claim 7, wherein the distance adjusting mechanism comprises a nozzle driving mechanism for adjusting the set position of the nozzle with respect to a vacuum chamber.

9. A supersonic beam apparatus according to claim 7, wherein the distance adjusting mechanism comprises a skimmer driving mechanism for adjusting the set position of the skimmer with respect to a vacuum chamber.

10. A supersonic beam apparatus according to claim 7, wherein when a flow rate of the gas injected from the nozzle is increased, the distance adjusting mechanism increases the distance between the nozzle and the skimmer as compared with the distance before the increase of the flow rate of the gas injected from the nozzle.

11. A supersonic beam apparatus according to claim 7, wherein when a flow rate of the gas injected from the nozzle is decreased, the distance adjusting mechanism decreases the distance between the nozzle and the skimmer as compared with the distance before the decrease of the flow rate of the gas injected from the nozzle.

12. A supersonic beam apparatus according to claim 6, wherein the position of the skimmer is closer to the nozzle than a closest position of the Mach disk to the nozzle.

13. A supersonic beam apparatus according to claim 6, wherein the position of the skimmer is closer to the nozzle than a position of the Mach disk when the flow rate of the gas injected from the nozzle is maximized.

14. A supersonic beam apparatus according to claim 6, wherein the gas flow rate control part limits the flow rate of the gas so that the position of the skimmer is closer to the nozzle than the position where the Mach disk is formed.

15. A supersonic beam apparatus according to claim 7, further comprising:
a vacuum gauge arranged on a vacuum chamber;
a pressure gauge for measuring a pressure of the gas injected from the nozzle;
a processing part for calculating a maximum position where the amount of cluster generation in the relationship of the amount of cluster generation with respect to the distance between the nozzle and the skimmer is maximized by receiving vacuum data from the vacuum gauge and pressure data from the pressure gauge; and
a distance measurement unit for measuring the distance between the nozzle and the skimmer,
wherein the distance adjusting mechanism receives position data of the maximum position where the amount of cluster generation is maximized from the processing part and adjusts the position of the nozzle or the skimmer so that the skimmer comes close to one of the maximum position where the amount of cluster generation is maximized and a predetermined position, based on distance data output from the distance measurement unit.

16. A supersonic beam apparatus according to claim 6, further comprising:
a vacuum gauge arranged on a vacuum chamber;
a pressure gauge for measuring a pressure of the gas injected from the nozzle;
a distance measurement unit for measuring the distance between the nozzle and the skimmer; and
a processing part for calculating a first pressure inside the vacuum chamber with which the amount of cluster generation is maximized or equals to a predetermined value, based on distance data output from the distance measurement unit and pressure data output from the pressure gauge
wherein the gas flow rate control part controls the flow rate of the gas so that the pressure inside the vacuum chamber does not exceeds the first pressure.

17. A method of forming a cluster ion beam, the method comprising:
generating a first beam by injecting a gas from a nozzle at a supersonic velocity into a vacuum;
generating a second beam containing a particle by a skimmer arranged between the nozzle and a Mach disk formed by the first beam; and
ionizing the particle in the second beam having passed through the skimmer by an ionization part.
